(19) United States
(12) Patent Application Publication
(10) Pub. No.: US 2018/0180988 A1
(43) Pub. Date: Jun. 28, 2018

(54) PHOTOMASK HAVING AN EXPOSURE CORRECTION FUNCTION

(71) Applicant: WUHAN CHINA STAR OPTOELECTRONICS TECHNOLOGY CO., LTD., Wuhan, Hubei (CN)

(72) Inventors: Chunqian ZHANG, Wuhan, Hubei (CN); Caiqin CHEN, Wuhan, Hubei (CN)

(21) Appl. No.: 15/312,073

(22) PCT Filed: Aug. 3, 2016
(86) PCT No.: PCT/CN2016/093068

§ 371 Date: Nov. 17, 2016

(30) Foreign Application Priority Data
Jul. 13, 2016 (CN) 201610550097.2

(51) Int. Cl. G03F 1/36; G03F 1/38

(52) U.S. Cl. CPC G03F 1/36; G03F 1/38

(57) ABSTRACT

A photomask having an exposure correction function includes a shading region and an exposure region enclosed by the shading region. The exposure region comprises a correction sub-region and an exposure sub-region. The correction sub-region is arranged on a periphery of an acute angle vertex of the exposure sub-region.

### BACKGROUND OF THE INVENTION

### 1. Field of the Invention

The present disclosure relates to the field of liquid crystal displays, and more particularly to a photomask having an exposure correction function.

### 2. Description of the Prior Art

Currently, liquid crystal displays (LCDs) are widely used in electronic displays, such as televisions, computer screens, notebook computers, and mobile telephones.

In the LCDs, in order to ensure deflection angle of liquid crystals, intensity of an electric field formed in a panel needs to be ensured. However, in a fringe field switching (FFS) mode, the electric field is at a horizontal arrangement, thus there is more need to ensure exposure accuracy of a pixel electrode, where further uniform electric field is used to make deflection of the liquid crystals uniform.

In manufacturing a photomask, when size of a pattern on the photomask is less than a minimum accuracy of an exposure machine, the pattern cannot be completely copied because of limited exposure accuracy. It is assumed that if the pattern of the photomask has an acute angle, after an exposure and etching process is performed, the pattern of the photomask forms a round corner instead. If the above photomask is used, the electric field is non-uniform, which effects deflection of the liquid crystals, further forming dark lanes, and affecting display quality and display.

Therefore, it is necessary to provide a photomask to solve the above issue of the prior art.

### SUMMARY OF THE INVENTION

In order to avoid that the pattern cannot be completely copied because of limited exposure accuracy, the present disclosure provides a photomask having an exposure correction function.

The present disclosure provides the photomask having the exposure correction function, where the photomask having the exposure correction function comprises a shading region and an exposure region enclosed by the shading region.

The exposure region comprises an exposure sub-region and a correction sub-region.

The correction sub-region is arranged on a periphery of an acute angle vertex of the exposure sub-region. The correction sub-region is connected with the exposure sub-region. Upon a condition that the correction sub-region is a circular region, a diameter of the circular region is less than a minimum exposure accuracy of an exposure machine. A long axial length of the oval region is parallel to a midcourt line of the acute angle and a short axial length of the oval region is less than the minimum exposure accuracy of the exposure machine.

The present disclosure provides the photomask having the exposure correction function, where the photomask having the exposure correction function comprises a shading region and an exposure region enclosed by the shading region. The exposure region comprises a correction sub-region and an exposure sub-region, where the correction sub-region is arranged on a periphery of an acute angle vertex of the exposure sub-region. In a traditional photomask, an acute angle of the exposure sub-region performs an exposure and etching process, and the acute angle of the exposure sub-region forms round corner, which causes non-uniformity of an electric field and affect deflection of liquid crystals. Thus, through exposure area is increased, when light passes through the circular region, the light generates diffraction, and the diffracted light and light irradiated on photoresist through portion of the acute angle mutually enhance, which increases intensity of the exposure and ability of the exposure of the periphery of the acute angle vertex, further desired pattern is obtained after exposure and etching process is performed and avoiding causing non-uniformity of the electric field. Thus, quality of liquid crystal products and display are improved.

In the photomask having the exposure correction function of the present disclosure, the correction sub-region is connected with the exposure sub-region. It is specific location of the correction sub-region.

In the photomask having the exposure correction function of the present disclosure, the correction sub-region comprises but not limited to a quasi-circular region.

In the photomask having the exposure correction function of the present disclosure, when the correction sub-region is a circular region, a diameter of the circular region is less than a minimum exposure accuracy of an exposure machine. Through shape and size of the correction sub-region are limited, correction is improved and display is improved.

In the photomask having the exposure correction function of the present disclosure, when the correction sub-region is an oval region, a long axial length of the oval region is parallel to a midcourt line of the acute angle and a short axial length of the oval region is less than a minimum exposure accuracy of an exposure machine. Through shape and size of the correction sub-region are limited, correction is improved and display is improved.

In the photomask having the exposure correction function of the present disclosure, the correction sub-region is separated from the exposure sub-region by the shading region. It is other specific location of the correction sub-region.

In the photomask having the exposure correction function of the present disclosure, the correction sub-region comprises but not limited to one of a quasi-circular region, an annual region and a fold line region.

In the photomask having the exposure correction function of the present disclosure, when the correction sub-region is a circular region, a diameter of the circular region is less than a minimum exposure accuracy of an exposure machine. Through shape and size of the correction sub-region are limited, correction is improved and display is improved.

In the photomask having the exposure correction function of the present disclosure, when the correction sub-region is an annular region, a width of the annular region is less than a minimum exposure accuracy of an exposure machine. Through shape and size of the correction sub-region are limited, correction is improved and display is improved.

In the photomask having the exposure correction function of the present disclosure, when the correction sub-region is a fold line region, a width of the fold line region is less than a minimum exposure accuracy of an exposure machine. Through shape and size of the correction sub-region are limited, correction is improved and display is improved.

The present disclosure provides the photomask having the exposure correction, where the photomask having the exposure correction function comprises a shading region and an exposure region enclosed by the shading region.

The exposure region comprises a correction sub-region and an exposure sub-region.

The correction sub-region is arranged on a periphery of an acute angle vertex of the exposure sub-region. The shading region comprises a main region and an extension region extending outward from the main region.

Compared with the prior art, the present disclosure provides the periphery of the acute angle vertex of the exposure sub-region of the photomask having the exposure correction function forms at least a correction sub-region. The correction sub-region replaces portion of the original acute angle vertex or the correction sub-region is arranged on the periphery of the acute angle vertex. Therefore, the correction sub-region is arranged on the periphery of the acute angle vertex of the exposure sub-region, and size of the acute angle is less than the minimum exposure accuracy of the exposure machine and the width of the correction sub-region is less than the minimum exposure accuracy of the exposure machine, which cannot affect exposure pattern. Namely, through exposure area is increased, when light passes through the circular region, the light generates diffraction, and the diffracted light and light irradiated on photoresist through portion of the acute angle mutually enhance, which increases intensity of the exposure and ability of the exposure of the periphery of the acute angle vertex, further desired pattern is obtained after an exposure and etching process is performed and avoiding causing non-uniformity of the electric field. Thus, quality of liquid crystal products and display are improved.

### BRIEF DESCRIPTION OF THE DRAWINGS

In order to describe clearly the embodiment in the present invention or the prior art, the following will introduce the drawings for the embodiment shortly. Obviously, the following description is only a few embodiments, for the common technical personnel in the field it is easy to acquire some other drawings without creative work.

FIG. 1 is a structural diagram of a correction sub-region being a circular region of a photomask of a first embodiment of the present disclosure.

FIG. 2 is a structural diagram of a correction sub-region being an oval region of a photomask of a second embodiment of the present disclosure.

FIG. 3 is a structural diagram of a correction sub-region being a circular region of a photomask of a third embodiment of the present disclosure.

FIG. 4 is a structural diagram of a correction sub-region being an annular region of a photomask of a fourth embodiment of the present disclosure.

FIG. 5 is a structural diagram of a correction sub-region being a fold line region of a photomask of a fourth embodiment of the present disclosure.

FIG. 6 is a structural diagram of a correction sub-region being a fold line region of a photomask of a fourth embodiment of the present disclosure where the fold line region becomes gradually narrower along two ends of cross point of the fold line region.

### DETAILED DESCRIPTION OF THE PREFERRED EMBODIMENTS

As shown in the drawings, wherein the same component symbols represent the same components. The principle of the present invention is implemented in a suitable computing environment for illustrative purposes. The following description is based on the specific illustrated embodiments of the present invention, which should not be construed as limiting the present invention, unless otherwise specified.

In the drawings, the components having similar structures are denoted by the same numerals.

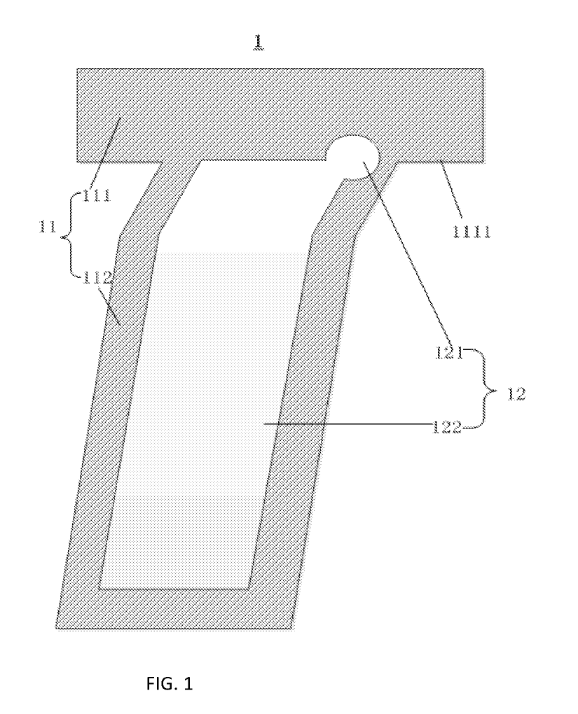

As shown in FIG. 1, FIG. 1 is a structural diagram of a photomask 1 having an exposure correction function of a preferable embodiment of the present disclosure. The photomask 1 comprises a shading region 11 and an exposure region 12, where the exposure region 12 is enclosed by the shading region 11. A dashed region in the drawings is the shading region 11, and a blank region in the drawings is the exposure region 12.

To be specific, the shading region 11 comprises a main region 111 and an extension region 112 extending outward from the main region 111. In the embodiment, the main region 111 is rectangular. The main region 111 comprises a bottom edge 1111. It should be understood that shape of the main region 111 is adjusted according to actual requirements in other embodiments, such as a square and a polygon.

In the embodiment, the extension region 112 obliquely extends from the bottom edge 1111 of the main region 111extension region, where the extension region 112 is approximately a U-shaped structure. In the embodiment, a head and a tail of the extension region 112 are connected with the bottom edge 1111 of the main region 111 to form the exposure region 12. It should be understood that number and shape of the extension region are adjusted according to actual requirements in other embodiments, as long as the extension region can be matched with the main region 111 to form the exposure region 12.

The exposure region 12 comprises an exposure sub-region 122 and a correction sub-region 121. To be specific, in the embodiment, the exposure sub-region 122 is approximately in the shape of a rhombus. Namely, the extension region 112 is matched with the main region 111 to form the exposure region 12 that is approximately in the shape of a rhombus. The exposure region 12 is located in a critical position of the main region 111 connected to the extension region 112 to form at least an acute angle vertex region having an acute angle. The correction sub-region 121 is arranged and formed on the at least the acute angle vertex region having the acute angle. Namely the correction sub-region 121 is arranged on a periphery of an acute angle vertex of the exposure sub-region 122.

To be specific, the correction sub-region 121 is connected with the exposure sub-region 122. Preferably, the correction sub-region comprises but is not limited to a quasi-circular region. In the embodiment, the correction sub-region 121 is a circular region, where a diameter of the circular region 121 is less than a minimum exposure accuracy of an exposure machine. In order to achieve good correction, the correction is better when a center of a circle of the circular region 121 is arranged on a diagonal of the at least acute angle vertex region, having the acute angle, through experimentation. Namely the acute angle pattern is restored, which avoids the acute angle pattern from forming a round corner after an exposure and etching process is performed because of limited exposure accuracy, further avoiding causing non-uniformity of the electric field.

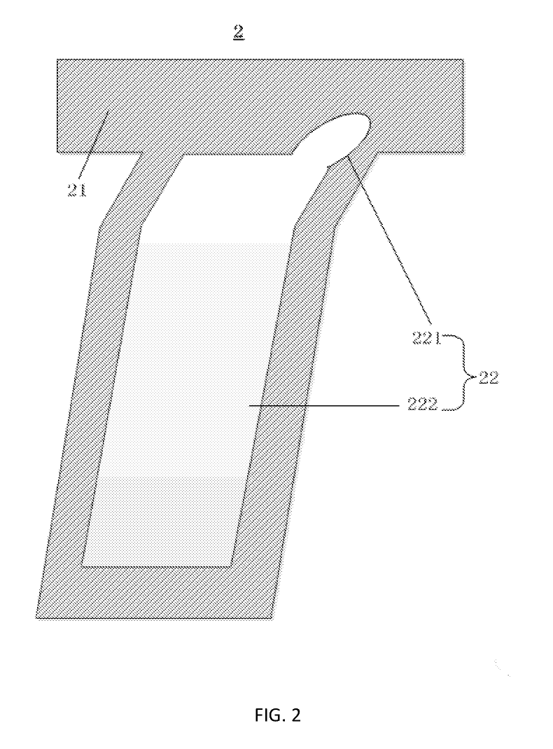

As shown in FIG. 2, FIG. 2 is a structural diagram of a photomask 2 having an exposure correction function of a preferable second embodiment of the present disclosure. The photomask 2 comprises a shading region 21 and an exposure region 22, where the exposure region 22 is enclosed by the shading region 21. Dashed region in drawings is the shading region 11, and a blank region in drawings is the exposure region 22. The exposure region 22 comprises an exposure sub-region 222 and a correction sub-region 221. Basic structure of the photomask 2 is same as structure of the photomask 1 of the first embodiment, thus, there is no specific description. The second embodiment is a different from the first embodiment in that the correction sub-region 221 is an oval region, where a short axial length of the oval region 221 is less than the minimum exposure accuracy of the exposure machine. In order to achieve good correction, the best correction is achieved when the at least the acute angle vertex region, having the acute angle, through experimentation. Namely the pattern having an acute angle is restored, which avoids the pattern from forming a round corner after an exposure and etching process are performed because of limited exposure accuracy, further avoiding causing non-uniformity of the electric field.

It should be understood that designed shape of the correction sub-region only achieves to increase an exposed area the acute angle vertex region having the acute angle of the exposure region. Specific location and size can be calculated according to some conditions, such as the exposure machine.

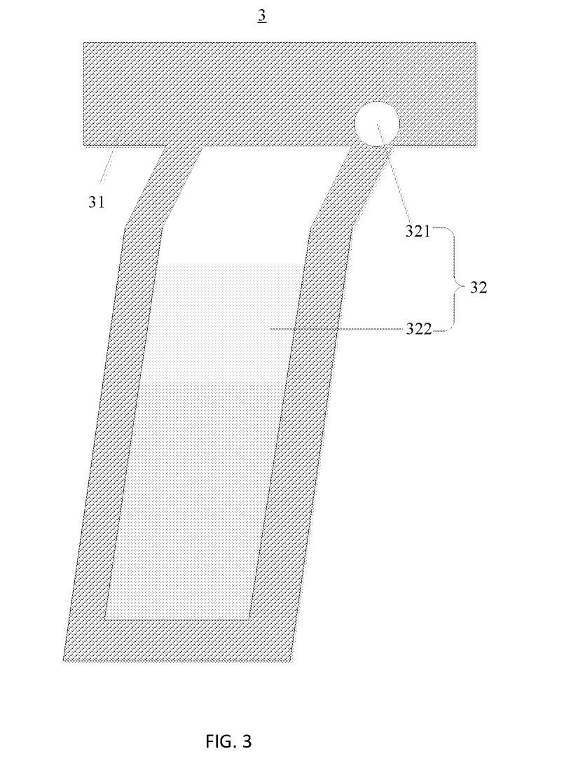

As shown in FIG. 3, FIG. 3 is a structural diagram of a photomask 3 having an exposure correction function of a preferable third embodiment of the present disclosure. The photomask 3 comprises a shading region 31 and an exposure region 32, where the exposure region 32 is enclosed by the shading region 31. Dashed region in drawings is the shading region 31, and a blank region in drawings is the exposure region 32. The exposure region 32 comprises an exposure sub-region 322 and a correction sub-region 321. Basic structure of the photomask 2 is same as a structure of the above photomask. The third embodiment is a difference from the above embodiment in that the correction sub-region 321 is arranged on a periphery of an acute angle vertex of the exposure sub-region 322 and is separated from the exposure sub-region 322. Namely, the correction sub-region 321 is separated from the exposure sub-region 322 by the shading region. To be specific, the correction region is correspondingly arranged on a main region of the shading region. The correction sub-region comprises, but not limited to, one of a quasi-circular region, an annual region and a fold line region.

In the embodiment, the correction sub-region 321 is a circular region, where a diameter of the circular region 321 is less than the minimum exposure accuracy of the exposure machine. Preferably, a center of the circular region 321 is on an extended line of a diagonal of the acute angle. When light passes through the circular region, the light generates diffraction, and the diffracted light and light irradiated on photoresist through portion of the acute angle mutually enhance, which increases intensity of the exposure and ability of the exposure, further increasing the exposure accuracy and restoring the acute angle pattern. Namely the acute angle pattern is restored, which avoids the acute angle pattern from forming a round corner after an exposure and etching process is performed because of limited exposure accuracy, further avoiding causing non-uniformity of the electric field. An edge of the circular region and the acute angle vertex have a certain distance, and the certain distance is set by the exposure machine depending on wavelength of the light, location of light source, and other conditions. For a person skilled in the art, it should be understood and calculated.

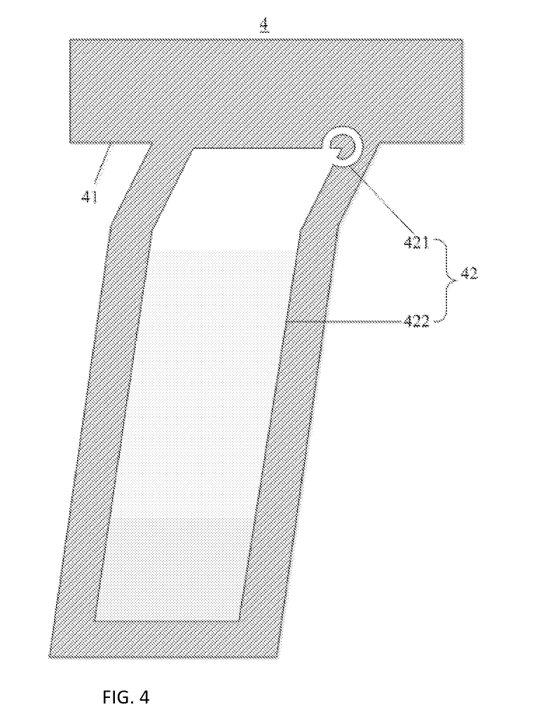

As shown in FIG. 4, FIG. 4 is a structural diagram of a photomask 4 having an exposure correction function of a preferable fourth embodiment of the present disclosure. The photomask 4 comprises a shading region 41 and an exposure region 42, where the exposure region 42 is enclosed by the shading region 41. Dashed region in drawings is the shading region 41, and a blank region in drawings is the exposure region 42. The exposure region 42 comprises an exposure sub-region 422 and a correction sub-region 421. When the correction sub-region 421 is an annular region, a width of the annular region 421 is less than the exposure accuracy of the exposure machine. Preferably, a center of the annular region 421 is on an extended line of the diagonal of the acute angle. When light passes through the annular region 421, the light generates diffraction, and the diffracted light and light irradiated on photoresist through portion of the acute angle mutually enhance, which increases intensity of the exposure and ability of the exposure, further increasing the exposure accuracy and restoring the acute angle pattern. Namely the acute angle pattern is restored, which avoids the acute angle pattern from forming a round corner after an exposure and etching process is performed because of limited exposure accuracy, further avoiding causing non-uniformity of the electric field. The circular region and the acute angle vertex have a certain distance, and the certain distance is set by the exposure machine depending on wavelength of the light, location of light source and other conditions. For a person skilled in the art, it should be understood and calculated.

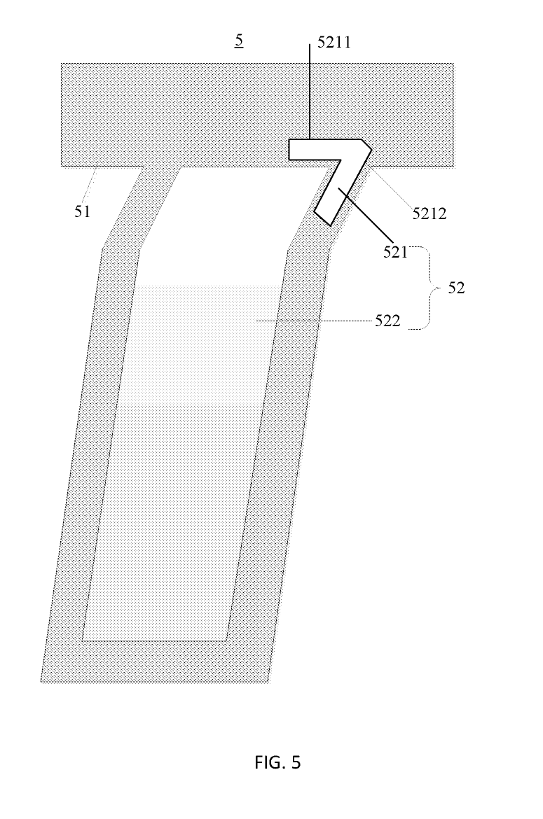

As shown in FIG. 5, FIG. 5 is a structural diagram of a photomask 5 having an exposure correction function of a preferable fifth embodiment of the present disclosure. The photomask 5 comprises a shading region 51 and an exposure region 52, where the exposure region 52 is enclosed by the shading region 51. Dashed region in drawings is the shading region 51, and a blank region in drawings is the exposure region 52. The exposure region 521 comprises an exposure sub-region 522 and a correction sub-region 521. When the correction sub-region 521 is a fold line region, to be specific, the fold line region comprises a first fold plate 5211 and a second fold plate 5212, where an end of the first fold plate 5211 is connected with the second fold plate 5212 to form a cross point. In the embodiment, a width of the first fold plate and a width second fold plate are uniform and consistent. To be specific, the width of the exposure region 521 is less than the exposure accuracy of the exposure machine. Preferably, the cross point of the fold line region 521 is on the extended line of the diagonal of the acute angle. When light passes through the annular region 421, the light generates diffraction, and the diffracted light and light irradiated on photoresist through portion of the acute angle mutually enhance, which increases intensity of the exposure and ability of the exposure, further increasing the exposure accuracy and restoring the acute angle pattern. Namely the acute angle pattern is restored, which avoids the acute angle pattern from forming a round corner after an exposure and etching process is performed because of limited exposure accuracy, further avoiding causing non-uniformity of the electric field. The fold line region and the acute angle vertex have a certain distance, and the certain distance is set by the exposure machine depending on wavelength of the light, location of light source, and other conditions. For a person skilled in the art, it should be understood and calculated.

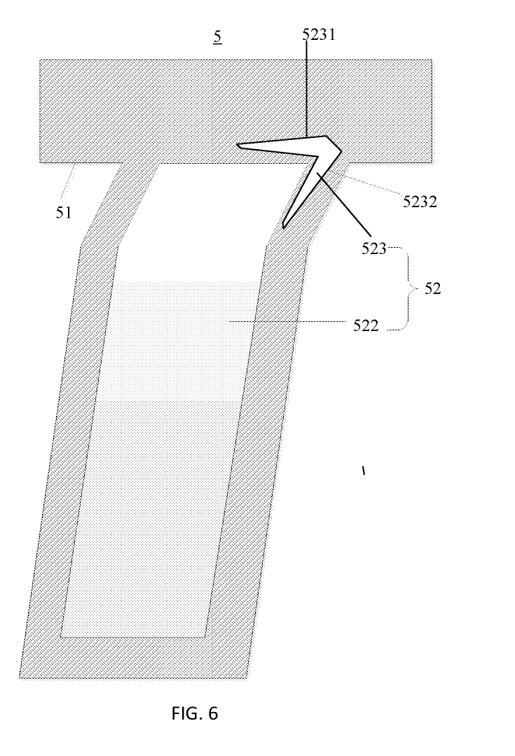

It should be understood that, as shown in FIG. 6 combined with FIG. 5, the width of the fold line region 523 can be gradually varied in FIG. 6. To be specific, the width of the first fold plate 5231 and the second fold plate 5232 are gradually narrow along two ends of the fold line region from the cross point, and a maximum width of the fold line region is less than the exposure accuracy of the exposure machine.

It should be understood that designed shape of the correction sub-region is not limited in the shape of the above embodiment and can be other structure, and there are not one by one described.

Compared with the prior art, the present disclosure provides the periphery of the acute angle vertex of the exposure sub-region of the photomask having the exposure correction function forms at least a correction sub-region. The correction sub-region replaces portion of original acute angle vertex or the correction sub-region is arranged on the periphery of the acute angle vertex. Therefore, the correction sub-region is arranged on the periphery of the acute angle vertex of the exposure sub-region, and size of the acute angle is less than the minimum exposure accuracy of the exposure machine and the width of the correction sub-region is less than the minimum exposure accuracy of the exposure machine, which cannot affect exposure pattern. Namely, through exposure area is increased, when light passes through the circular region, the light generates diffraction, and the diffracted light and light irradiated on photoresist through portion of the acute angle mutually enhance. This increases intensity of the exposure and ability of the exposure of the periphery of the acute angle vertex, further desired pattern is obtained after an exposure and etching process is performed and avoiding causing non-uniformity of the electric field. Thus, quality of liquid crystal products and display are improved.

It should be understood that the present disclosure has been described with reference to certain preferred and alternative embodiments which are intended to be exemplary only and do not limit the full scope of the present disclosure as set fourth in the appended claims.

1. A photomask having an exposure correction function, comprising
a shading region; and
an exposure region enclosed by the shading region;
wherein the exposure region comprises an exposure sub-region and a correction sub-region; the correction sub-region is arranged on a periphery of an acute-angle vertex of the exposure sub-region, the correction sub-region is connected with the exposure sub-region; upon a condition that the correction sub-region is a circular region, a diameter of the circular region is less than a minimum exposure accuracy of an exposure machine; upon a condition that the correction sub-region is an oval region, a long axial length of the oval region is parallel to an angular bisector of the acute angle and a short axial length of the oval region is less than the minimum exposure accuracy of the exposure machine.

2. A photomask having an exposure correction function, comprising
a shading region; and
an exposure region enclosed by the shading region;
wherein the exposure region comprises a correction sub-region and an exposure sub-region;
wherein the correction sub-region is arranged on a periphery of an acute angle vertex of the exposure sub-region; the shading region comprises a main region and an extension region extending outward from the main region.

3. The photomask having the exposure correction function as claimed in claim 2, wherein the correction sub-region is connected with the exposure sub-region.

4. The photomask having the exposure correction function as claimed in claim 3, wherein the correction sub-region comprises a quasi-circular region or a circular region.

5. The photomask having the exposure correction function as claimed in claim 4, wherein the correction sub-region is [[a]] the circular region, and a diameter of the circular region is less than a minimum exposure accuracy of an exposure machine.

6. The photomask having the exposure correction function as claimed in claim 4, wherein the correction sub-region is an oval region, and a long axial length of the oval region is parallel to a midcourt line an angular bisector of the acute angle and a short axial length of the oval region is less than a minimum exposure accuracy of an exposure machine.

7. The photomask having the exposure correction function as claimed in claim 2, wherein the correction sub-region is separated from the exposure sub-region by the shading region.

8. The photomask having the exposure correction function as claimed in claim 7, wherein the correction sub-region comprises but not limited to one of a quasi-circular region, an annual region, or a fold line region.

9. The photomask having the exposure correction function as claimed in claim 8, wherein the correction sub-region is a circular region, and a diameter of the circular region is less than a minimum exposure accuracy of an exposure machine.

10. The photomask having the exposure correction function as claimed in claim 8, wherein the correction sub-region is an annular region, and a width of the annular region is less than a minimum exposure accuracy of an exposure machine.

11. A photomask having an exposure correction function, comprising
a shading region; and
an exposure region enclosed by the shading region;
wherein the exposure region comprises a correction sub-region and an exposure sub-region;
wherein the correction sub-region is arranged on a periphery of an acute angle vertex of the exposure sub-region.

12. The photomask having the exposure correction function as claimed in claim 11, wherein the correction sub-region is connected with the exposure sub-region.

13. The photomask having the exposure correction function as claimed in claim 12, wherein the correction sub-region comprises but not limited to a quasi-circular region or a circular region.

14. The photomask having the exposure correction function as claimed in claim 13, wherein the correction sub-region is the circular region, and a diameter of the circular region is less than a minimum exposure accuracy of an exposure machine.

15. The photomask having the exposure correction function as claimed in claim 13, wherein the correction sub-region is an oval region, and a long axial length of the oval region is parallel to an angular bisector of the acute angle and a short axial length of the oval region is less than a minimum exposure accuracy of an exposure machine.

16. The photomask having the exposure correction function as claimed in claim 11, wherein the correction sub-region is separated from the exposure sub-region by the shading region.

17. The photomask having the exposure correction function as claimed in claim 16, wherein the correction sub-region comprises a quasi-circular region, an annual region or a fold line region.

18. The photomask having the exposure correction function as claimed in claim 17, wherein the correction sub-region is a circular region, a diameter of the circular region is less than a minimum exposure accuracy of an exposure machine.

19. The photomask having the exposure correction function as claimed in claim 17, wherein the correction sub-region is an annular region, a width of the annular region is less than a minimum exposure accuracy of an exposure machine.

20. The photomask having the exposure correction function as claimed in claim 17, wherein the correction sub-region is a fold line region, and a width of the fold line region is less than a minimum exposure accuracy of an exposure machine.
